(19) United States
(12) Patent Application Publication
(10) Pub. No.: US 2009/0056795 A1
(43) Pub. Date: Mar. 5, 2009

(54) ELECTROLYTE FOR SOLAR CELL AND SOLAR CELL HAVING THE SAME

(76) Inventors: Moon-sung Kang, Yongin-si (KR); Ji-won Lee, Yongin-si (KR); Byong-cheol Shin, Yongin-si (KR); Kang-Jin Kim, Seoul (KR); Jae-pil Lee, Seoul (KR)

Correspondence Address: STEIN, MCEWEN & BUI, LLP, 1400 EYE STREET, NW, SUITE 300, WASHINGTON, DC, 20005, US

(21) Appl. No.: 12/168,334

(22) Filed: Jul. 7, 2008

(30) Foreign Application Priority Data
Aug. 30, 2007 (KR) 2007-87690

(51) Int. Cl. H01L 31/00

(52) U.S. Cl. 136/252

(57) ABSTRACT

An electrolyte for a solar cell, includes a heat treatment product of an imidazole, a C1-C20 diiodoalkane, and iodine (I₂). The electrolyte is an ionic gel-type electrolyte, which is injected into a solar cell with a low viscosity in a liquid form, and then gelated at a low temperature in the range of 60° C. or less. Thus, the electrolyte may be used in the manufacture of the solar cell.

### CROSS-REFERENCE TO RELATED APPLICATIONS

This application claims the benefit of Korean Application No. 2007-87690, filed Aug. 30, 2007, in the Korean Intellectual Property Office, the disclosure of which is incorporated herein by reference.

### BACKGROUND OF THE INVENTION

1. Field of the Invention

Aspects of the present invention relate to an electrolyte for a solar cell and a solar cell including the same. More particularly, aspects of the present invention relate to an electrolyte for a solar cell, the electrolyte having improved stability and durability, and a solar cell including the electrolyte, thereby having high photoelectric conversion efficiency and longer lifespan.

2. Description of the Related Art

Dye-sensitized solar cells are photoelectrochemical solar cells that use photosensitive dye molecules capable of absorbing visible rays to generate electron-hole pairs and an oxide semiconductor electrode comprising titanium dioxide to transfer the generated electrons. A dye-sensitized solar cell includes a photocathode that includes a semiconductor oxide nanoparticle layer onto which dye molecules are adsorbed, a counter electrode including a platinum catalyst, and an electrolyte containing a redox ion pair. The electrolyte is a core element that determines the photoelectric conversion efficiency and durability of the solar cell.

Conventional dye-sensitized solar cells typically use a liquid electrolyte including a volatile organic solvent (Korean Patent Publication No. 2001-0030478). A liquid electrolyte has excellent ionic conductivity, and thus the photoelectric conversion efficiency tend to be excellent. However, volatilization and leakage of the liquid electrolyte may easily occur so that the durability of the solar cell is degraded. Therefore, there is an urgent need to develop a semi-solid electrolyte that can be used instead of the liquid electrolyte.

As methods of preparing a semi-solid electrolyte, a method of adding a plasticizer to a polymer for forming an electrolyte, a method of adding an organic monomolecular gelation agent to a liquid electrolyte, a method of using polymerization or cross-linking of an organic monomolecule, a method of using a monomolecule having a hydrogen-bonding group, and the like have been tried.

However, semi-solid electrolytes prepared by the above-mentioned methods typically have poor stability at increased temperatures and typically do not have satisfactory ionic conductivity. Thus, there is a need for developing a new electrolyte.

### SUMMARY OF THE INVENTION

Aspects of the present invention provide an electrolyte for a solar cell, the electrolyte having improved stability and durability and high ionic conductivity, and a solar cell including the same, thereby having high photoelectricity conversion efficiency and longer lifespan.

According to an embodiment of the present invention, there is provided a composition comprising a complex salt of an imidazole and a C₁-C₂₀ diiodoalkane.

According to another embodiment of the present invention, there is provided a composition that is a reaction product obtained by heat-treatment of a complex salt of an imidazole and a C₁-C₂₀ diiodoalkane, and iodine.

According to another embodiment of the present invention, there is provided an electrolyte for a solar cell, comprising: a complex salt of an imidazole and a C₁-C₂₀ diiodoalkane and an iodide ion (I⁻/I₃⁻). The electrolyte may be produced from the complex salt of the imidazole and C₁-C₂₀ diiodoalkane and I₂.

According to another embodiment of the present invention, there is provided an electrolyte for a solar cell, comprising: a cation and an iodide ion (I⁻/I₃⁻), which are produced from a hydrolyzed, dehydrated and condensed product of a complex salt of a silane substituted imidazole and C₁-C₂₀ diiodoalkane and iodine (I₂).

According to and aspect of the present invention, the amount of the iodide ion may be in the range of 10 to 30 parts by weight based on 100 parts by weight of the total weight of the electrolyte.

According to another embodiment of the present invention, there is provided a solar cell comprising: a first electrode and a second electrode, which face each other; a porous film that is disposed between the first electrode and the second electrode and that includes at least one dye adsorbed thereon; and an electrolyte as described above disposed between the first electrode and the second electrode.

According to another embodiment of the present invention, there is provided a method of manufacturing a solar cell, comprising injecting a liquid composition to form an electrolyte between a first electrode and a second electrode, wherein the liquid composition to form an electrolyte comprises an imidazole, a C₁-C₂₀ diiodoalkane and iodine; and heating the injected liquid composition to form a gelled electrolyte comprising a complex salt of the imidazole and C₁-C₂₀ diiodoalkane, and an iodide ion (I⁻/I₃⁻)

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a flowchart for explaining a process of forming an ionic gel in an electrolyte according to aspects of the present invention;

FIG. 2 is a view illustrating an ion conduction mechanism in an electrolyte according to aspects of the present invention;

FIG. 3 is a cross-sectional view illustrating a solar cell according to an embodiment of the present invention; and

FIG. 4 is a graph showing the results of evaluating the durability of solar cells prepared in Example 3 and Comparative Example 1.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

Aspects of the present invention provide an electrolyte comprising a heat treatment product of an imidazole, a C₁-C₂₀ diiodoalkane, and iodine (I₂).

The heat treatment product comprises a complex salt of an imidazole cation and a C₁-C₂₀ diiodoalkane anion and an iodide ion (I⁻/I₃⁻), which is produced from t the imidazole and C₁-C₂₀ diiodoalkane and I₂.

According to aspects of the present invention, the structure of the complex salt of the imidazole cation and C₁-C₂₀ diiodoalkane anion can be confirmed by a Fourier transform infrared (FT-IR), ion analysis, or the like.

When the electrolyte according to aspects of the present invention is prepared, the imidazole cation and C₁-C₂₀ diiodoalkane anion bind to each other in the presence of iodine to produce an iodide ion (I⁻/I₃⁻) and the complex salt thereof and to be gelated. In addition, the addition of a separate solvent and iodide ion is unnecessary.

The electrolyte according to aspects of the present invention is a gel-type ionic electrolyte that can be substituted for a liquid electrolyte that may volatilize or leak, is in the form of a semi-solid, and by which long-term stability of a solar cell can be obtained.

According to aspects of the present invention, the imidazole cation is not particularly limited and can be the cation of any compound having an imidazole moiety. As a non-limiting example, the imidazole that forms the cation may be a compound represented by Formula 1 below.

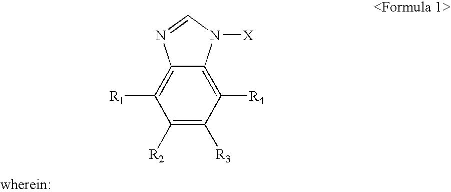

R₁, R₂, R₃, and R₄ are each independently hydrogen, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₆-C₂₀ aryloxy group, a substituted or unsubstituted C₂-C₂₀ heteroaryl group, a substituted or unsubstituted C₂-C₂₀ heteroaryloxy group, a substituted or unsubstituted C₄-C₁₀ carbocyclic group, a hydroxyl group, a cyano group, or a halogen atom,
X is hydrogen, a substituted or unsubstituted C₁-C₂₀ alkyl group, a substituted or unsubstituted C₆-C₂₀ aryl group, or a group represented by a structural formula below,

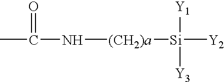

Y₁, Y₂, and Y₃ are each independently a halogen atom, a hydroxyl group, a C₁-C₁₀ alkyl group, a C₁-C₁₀ alkoxy group, or hydrogen, and
a is an integer in the range of 1 to 10.

As further non-limiting examples in addition to the non-limiting example provided by compound of Formula 1, the imidazole that forms the cation may be at least one selected from the group consisting of 2-ethylimidazole, 1-acetylimidazole, 2-ethyl-4-methylimidazole, 1-allylimidazole, 2-methyl-5-nitroimidazole, ethyl 4-methyl-5-imidazolecarboxylate, 2-phenylimidazole, 1-vinylimidazole, 4,5-dichloroimidazole, 5-chloro-1-methylimidazole, 5-methylbenzimidazole, 5-chloro-1-ethyl-2-methylimidazole, 4-methyl-2-phenylimidazole, methyl-2-nitro-1-imidazoleacetate, methyl 4-imidazolecarboxylate, 2-butyl-4-chloro-5-(hydroxymethyl)imidazole, 2-butyl-4-chloro-5-formylimidazole, 5-bromo-1-methylimidazole, 2-bromo-1-methyl-1H-imidazole, 2-iodoimidazole, 2-methylimidazole, 2-chloro-1H-imidazole, 2-methyl-5-nitroimidazole, 2-(chloromethyl)benzimidazole, 5,6-dimethylbenzimidazole, 1,2-dimethylimidazole, 4,5-diphenylimidazole, 2-ethyl-4-methylimidazole, 2-methylbenzimidazole, 1-(3-triethoxysilyl)propyl)-2-ethyl-2,5-dihydroxy-1H-imidazole, 2-ethyl-2,5-dihydro-1-(3-(trimethoxysilyl)propyl)-1H-imidazole, 1-(2-(triethoxysilyl)ethyl)-2-ethyl-2,5-dihydro-1H-imidazole, 2-ethyl-2,5-dihydro-1-((trimethoxysilyl)methyl)-1H-imidazole, 1-((triethoxysilyl)methyl)-2-ethyl-2,5-dihydro-1H-imidazole, 1-(3-(triethoxysilyl)propyl)-2-ethyl-2,5-dihydro-4-methyl-1H-imidazole, 2-ethyl-2,5-dihydro-1-(3-(trimethoxysilyl)propyl)-4-methyl-1H-imidazole, 1-(2-triethoxysilyl)ethyl)-2-ethyl-2,5-dihydro-4-methyl-1H-imidazole, 2-ethyl-2,5-dihydro-1-((trimethoxysilyl)methyl)-4-methyl-1H-imidazole, 1-((triethoxysilyl)methyl)-2-ethyl-2,5-dihydro-4-methyl-1H-imidazole, N-(3-triethoxysilyl)propyl)-1-methyl-1H-imidazole-5-amine, N-(3-(triethoxysilyl)propyl)-2-phenyl-2H-imidazole-1(5H)-carboxamide, N-(3-trimethoxysilyl)propyl)-1-methyl-1H-imidazole-5-amine, N-(3-(triethoxysilyl)propyl)-5-methyl-2H-benz[d]imidazole-1(4H)-carboxamide, N-(3-(triethoxysilyl)propyl)-4-methyl-2-phenyl-2H-imidazole-1(5H)-carboxamide, N-(3-(triethoxysilyl)propyl)-5,6-dimethyl-2H-benz[d]imidazole-1(4H)-carboxamide, N-(3-(triethoxysilyl)propyl)-4,5-diphenyl-1H-imidazole-1-carboxamide, N-(3-(triethoxysilyl)propyl)-2-methyl-2H-benz[d]imidazole-1(4H)-carboxamide, N-3-(triethoxysilyl)propyl)-2-ethyl-4-methyl-1H-imidazole-1-carboxamide, 1-(3-(triethoxysilyl)propyl)-2,7a-dihydro-5-methyl-1H-benz[d]imidazole, 2,7a-dihydro-1-(3-(trimethoxysilyl)propyl)-5-methyl-1H-benz[d]imidazole, 2,7a-dihydro-1-((trimethoxysilyl)methyl)-5-methyl-1H-benz[d]imidazole, 1-(2-(triethoxysilyl)ethyl)-2,7a-dihydro-5-methyl-1H-benz[d]imidazole, 1-((triethoxysilyl)methyl)-2,7a-dihydro-5-methyl-1H-benz[d]imidazole, 1-(3-(triethoxysilyl)propyl)-2,5-dihydro-4-methyl-2-phenyl-1H-imidazole, 2,5-dihydro-1-(3-(trimethoxysilyl)propyl)-4-methyl-2-phenyl-1H-imidazole, 2,5-dihydro-1-((trimethoxysilyl)methyl)-4-methyl-2-phenyl-1H-imidazole, 1-(2-(triethoxysilyl)ethyl)-2,5-dihydro-4-methyl-2-phenyl-1H-imidazole, 1-((triethoxysilyl)methyl)-2,5-dihydro-4-methyl-2-phenyl-1H-imidazole, 1-(3-(triethoxysilyl)propyl)-2,4-dihydro-5,6-dimethyl-1H-benz[d]imidazole, 2,4-dihydro-1-(3-(trimethoxysilyl)propyl)-5,6-dimethyl-1H-benz[d]imidazole, 2,4-dihydro-1-((trimethoxysilyl)methyl)-5,6-dimethyl-1H-benz[d]imidazole, 1-(2-(triethoxysilyl)ethyl)-2,4-dihydro-5,6-dimethyl-1H-benz[d]imidazole, 1-((triethoxysilyl)methyl)-2,4-dihydro-5,6-dimethyl-1H-benz[d]imidazole, 1-(3-(triethoxysilyl)propyl)-4,5-diphenyl-1H-imidazole, 1-((trimethoxysilyl)methyl)-4,5-diphenyl-1H-imidazole, 1-(3-(trimethoxysilyl)propyl)-4,5-diphenyl-1H-imidazole, 1-(2-(triethoxysilyl)ethyl)-4,5-diphenyl-1H-imidazole, 1-((triethoxysilyl)methyl)-4,5-diphenyl-1H-imidazole, 1-(3-(triethoxysilyl)propyl)-2-ethyl-4-methyl-1H-imidazole, 2-ethyl-1-((trimethoxysilyl)methyl)-4-methyl-1H-imidazole, 2-ethyl-1-(3-(trimethoxysilyl)propyl)-4-methyl-1H-imidazole, 1-(2-(triethoxysilyl)ethyl)-2-ethyl-4-methyl-1H-imidazole, 1-((triethoxysilyl)methyl)-2-ethyl-4-methyl-1H-imidazole, 1-(3-(triethoxysilyl)propyl)-2-ethyl-1H-benz[d]imidazole, 1-((trimethoxysilyl)methyl)-2-ethyl-1H-benz[d]imidazole, 1-(3-(trimethoxysilyl)propyl)-2-methyl-1H-benz[d]imidazole, 1-(2-(triethoxysilyl)ethyl)-2-methyl-1H-benz[d]imidazole, 1-((triethoxysilyl)methyl)-2-methyl-1H-benz[d]imidazole, N-(3-(triethoxysilyl)propyl)-1-ethyl-2-methyl-1H-imidazole-5-amine, N-(3-(triethoxysilyl)propyl)-1,2-dimethyl-1H-imidazole-5-amine, 1-ethyl-N-(3-(trimethoxysilyl)propyl)-2-methyl-1H-imidazole-5-amine, and N-(3-(trimethoxysilyl)propyl)-1,2-dimethyl-1H-imidazole-5-amine (refer to following fomulae).

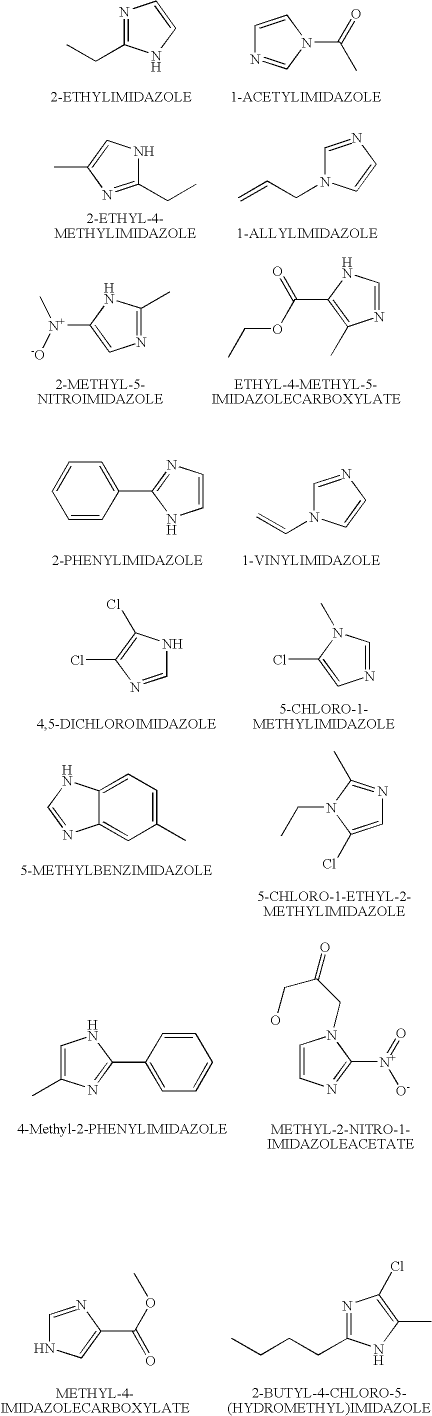

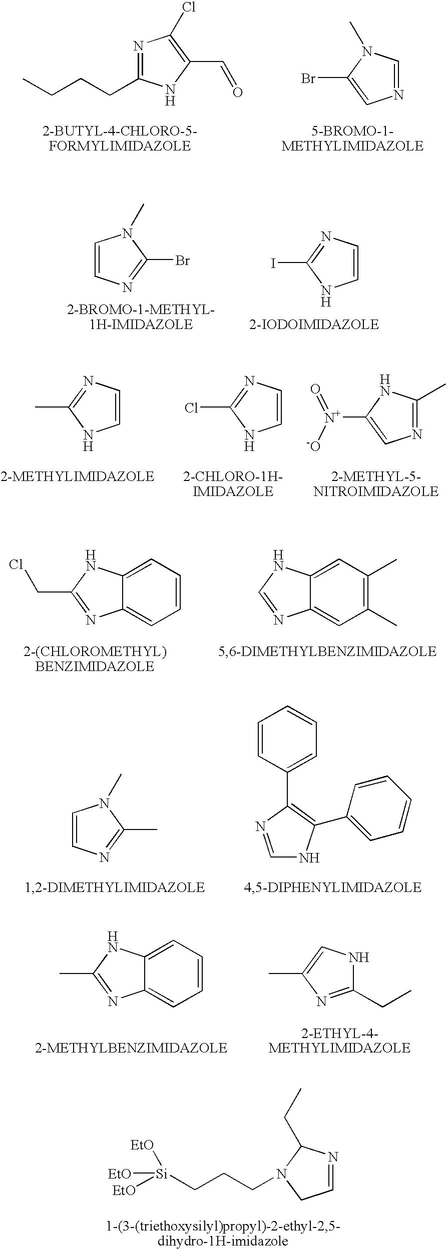

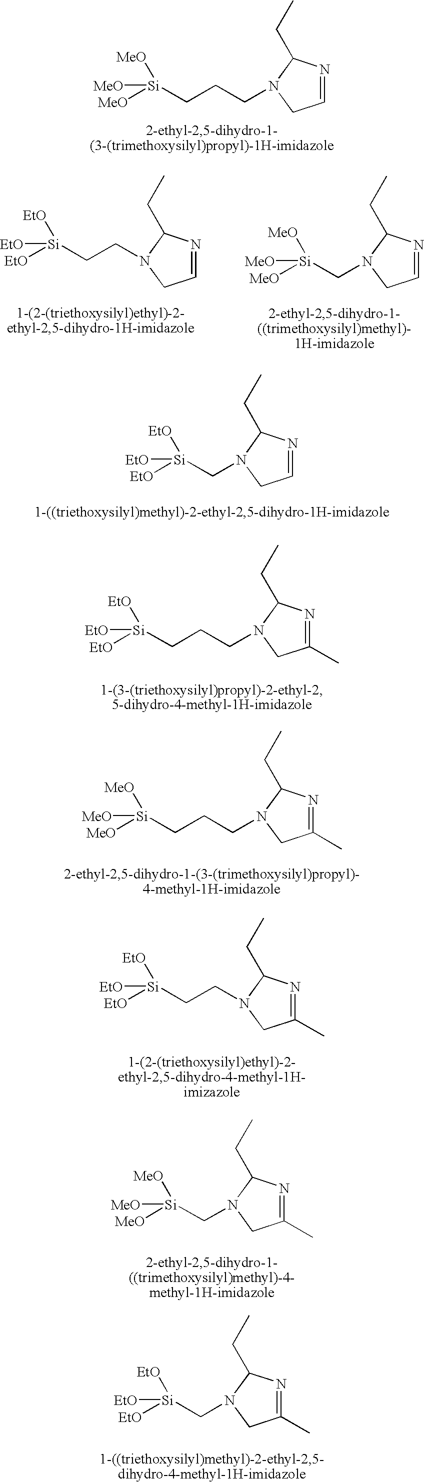

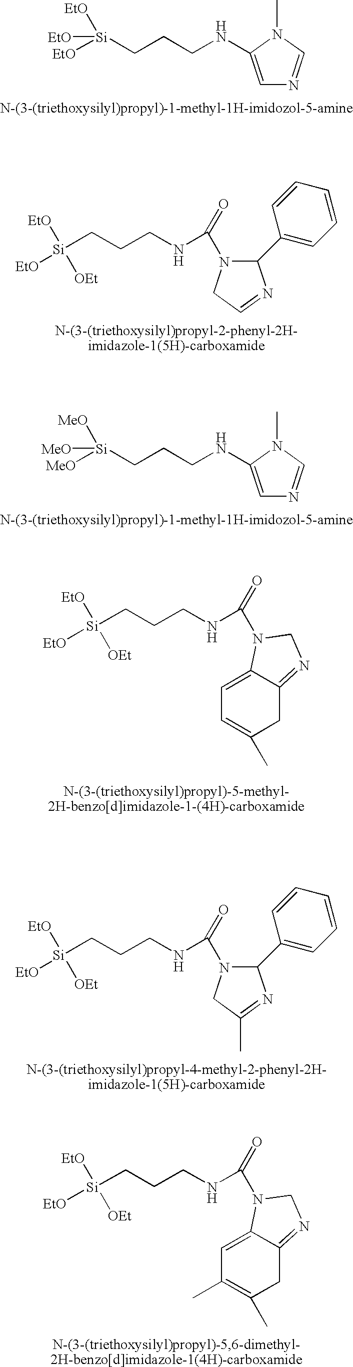

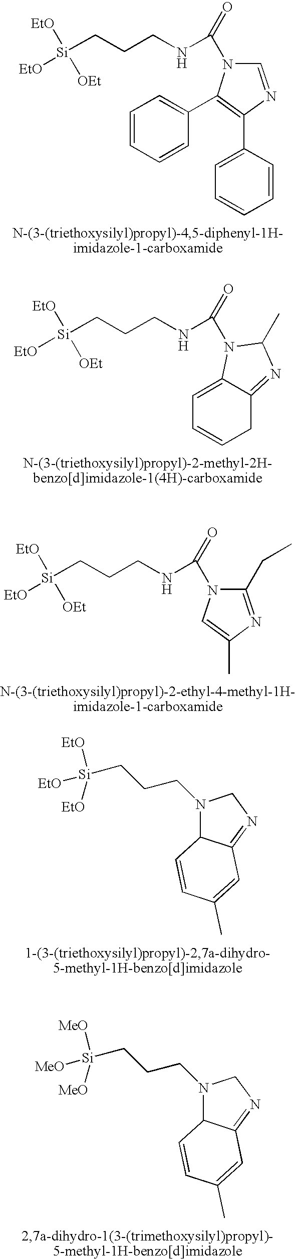

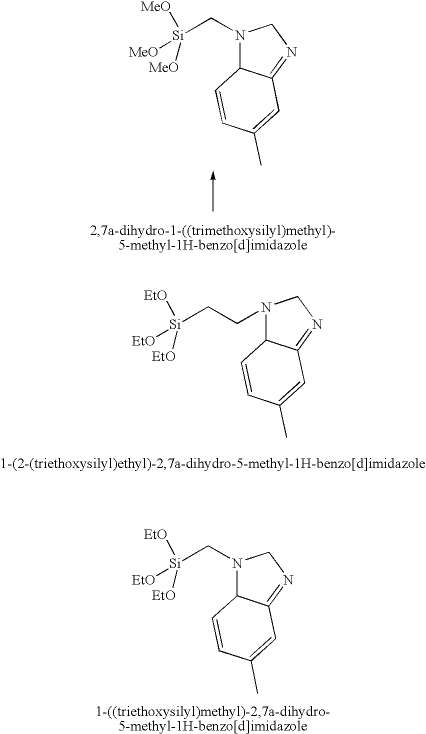

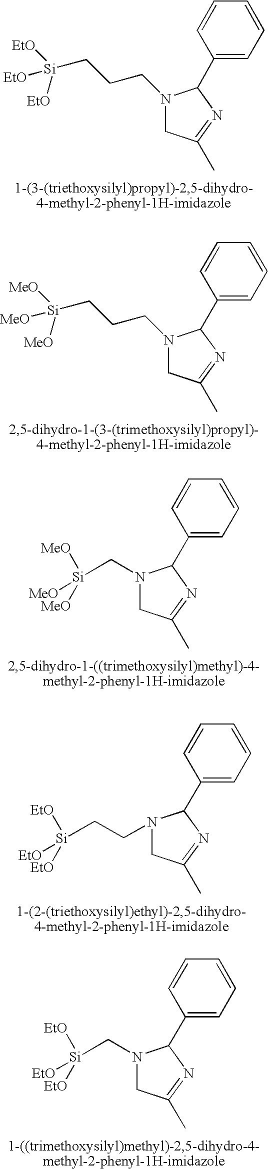

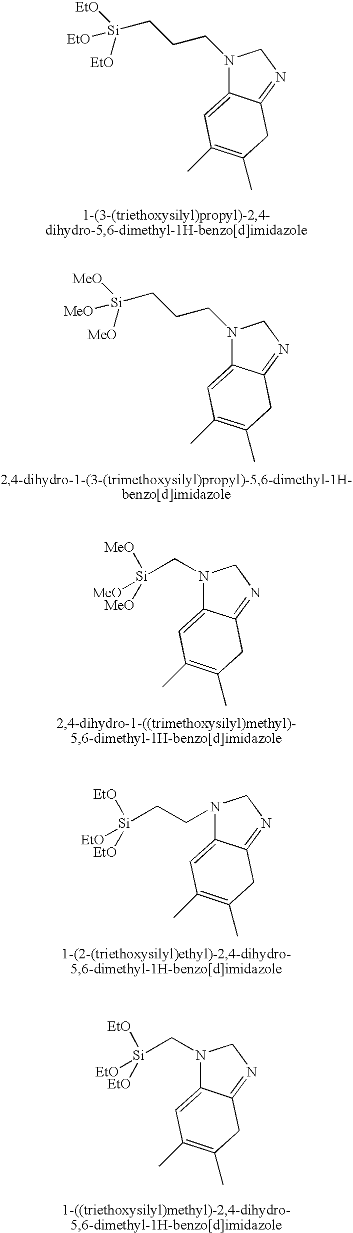

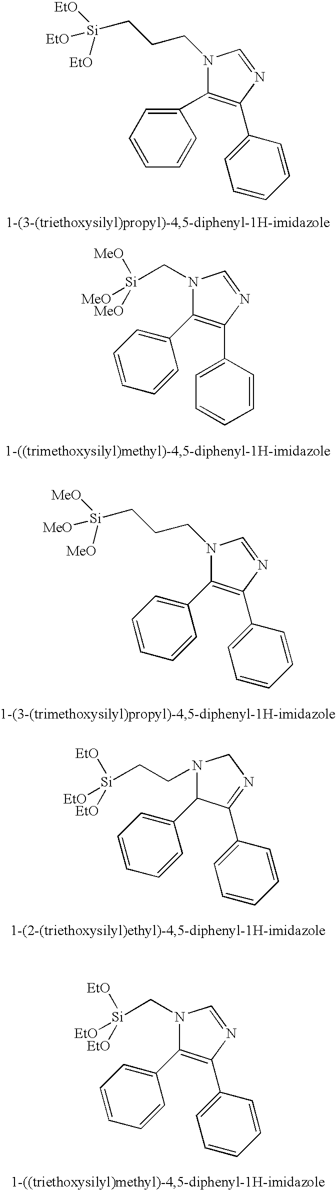

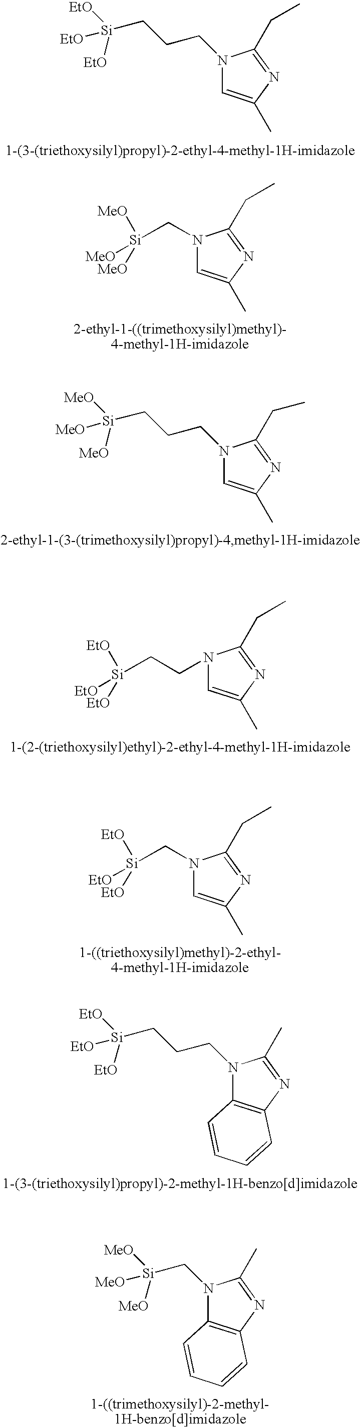

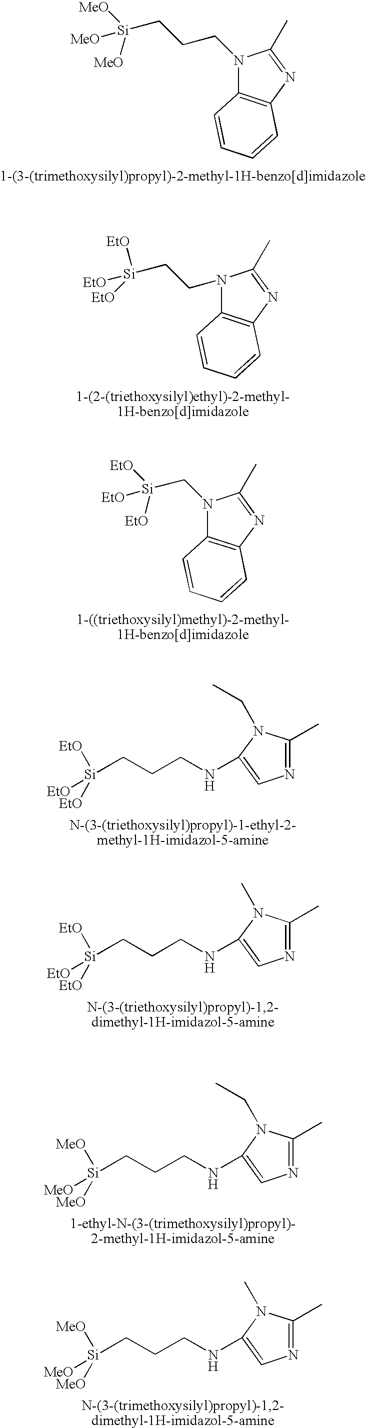

As a more specific, non-limiting example, the compound of Formula 1 may be a compound represented by Formula 2 below.

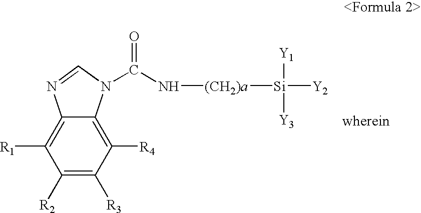

R₁, R₂, R₃, and R₄ are each independently hydrogen, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₆-C₂₀ aryloxy group, a substituted or unsubstituted C₂-C₂₀ heteroaryl group, a substituted or unsubstituted C₂-C₂₀ heteroaryloxy group, a substituted or unsubstituted C₄-C₁₀ carbocyclic group, a hydroxy group, a cyano group, or a halogen atom,
Y₁, Y₂, and Y₃ are each independently a halogen atom, a hydroxyl group, a C₁-C₁₀ alkyl group, a C₁-C₁₀ alkoxy group, or hydrogen, and
a is an integer in the range of 1 to 10.

As non-limiting examples, the compound represented by Formula 2 may be at least one selected from the group consisting of N-(3-(triethoxysilyl)propyl)-2H-benz[d]imidazole-1(4H)-carboxamide, N-(3-(triethoxysilyl)propyl)-5-methyl-2H-benz[d]imidazole-1(4H)-carboxamide, and N-(3-(triethoxysilyl)propyl)-5,6-dimethyl-2H-benz[d]imidazole-1(4H)-carboxamide.

As non-limiting examples, the C₁-C₂₀ diiodoalkane used herein to form the C₁-C₂₀ diiodoalkane anion may be at least one selected from diiodohexane, diiodoheptane, and diiodononane.

As a non-limiting example, the complex salt of the imidazole and C₁-C₂₀ diiodoalkane may be a compound represented by Formula 3 below.

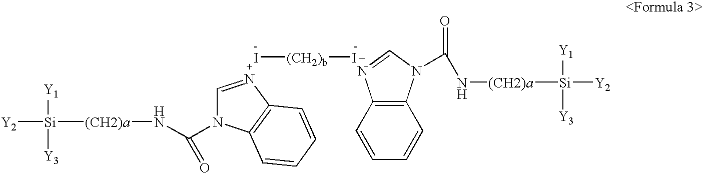

wherein Y₁, Y₂, and Y₃ are each independently a halogen atom, a hydroxyl group, a C₁-C₁₀ alkyl group, a C₁-C₁₀ alkoxy group, or hydrogen,
a is an integer in the range of 1 to 10, and
b is an integer in the range of 1 to 20.

According to an embodiment of the present invention, the complex salt of the imidazole and C₁-C₂₀ diiodoalkane may be a compound represented by Formula 4 below where in Formula 3, Y₁, Y₂, and Y₃ are each independently an ethoxy group, a is 3, and b is 6.

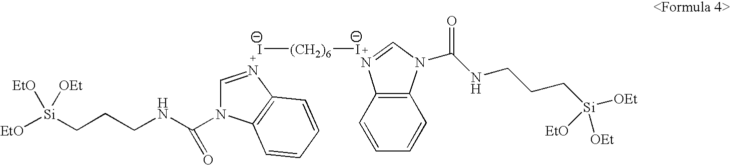

wherein OEt (or EtO) refers to an ethoxy group.

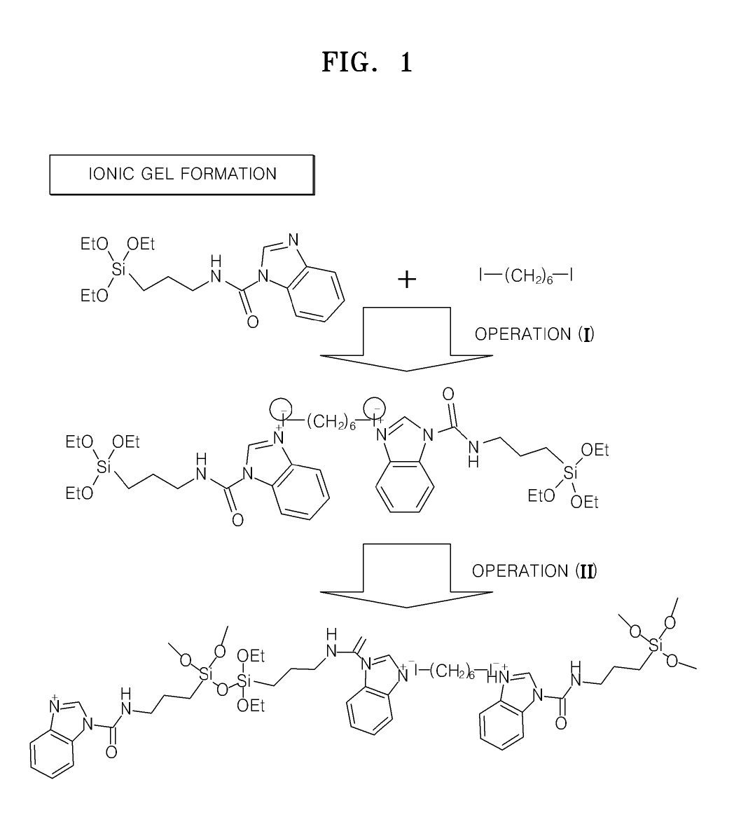

In Formula 4, when the imidazole and the C₁-C₂₀ diiodoalkane form a complex salt, a cation (+) is formed at a nitrogen atom of the imidazole, an anion (−) is formed at the iodine of the C₁-C₂₀ diiodoalkane. The anion forms an ionic bond with the corresponding cation and an iodide ion (I−/I3−) by interaction with iodine, and thus gelation proceeds (Operation (I) of FIG. 1).

The amount of the iodide ion may be in the range of from 10 to 30 parts by weight based on 100 parts by weight of the total weight of the electrolyte.

Aspects of the present invention also provide an electrolyte for a solar cell, the electrolyte comprising a resultant obtained by performing hydrolysis and dehydration and polycondensation of a heat treatment product of a silane-substituted imidazole, C₁-C₂₀ diiodoalkane and iodine.

The resultant may comprise a cation and an iodide ion (I⁻/I₃⁻), which are produced from a hydrolyzed, dehydrated and condensed product of a complex salt of a silane substituted imidazole and C₁-C₂₀ diiodoalkane and iodine (I₂).

As a non-limiting example, the silane-substituted imidazole may have a structure in which a silane group represented by the following formula is substituted, as in the compound of Formula 2 described above.

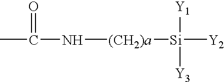

wherein Y₁, Y₂, and Y₃ are each independently a halogen atom, a hydroxyl group, a C₁-C₁₀ alkyl group, a C₁-C₁₀ alkoxy group, or hydrogen; and
a is an integer in the range of 1 to 10.

The imidazole has a silane group, and thus induces an additional chemical bonding (condensation). Therefore, it is easy to adjust the gelation properties of the electrolyte.

As further non-limiting examples in addition to the non-limiting example of a silane-substituted compound in Formula 2, the silane-substituted imidazole according to aspects of the present invention may be, at least one compound selected from the group consisting of 1-(3-triethoxysilyl)propyl)-2-ethyl-2,5-dihydroxy-1H-imidazole, 2-ethyl-2,5-dihydro-1-(3-(trimethoxysilyl)propyl)-1H-imidazole, 1-(2-(triethoxysilyl)ethyl)-2-ethyl-2,5-dihydro-1H-imidazole, 2-ethyl-2,5-dihydro-1-((trimethoxysilyl)methyl)-1H-imidazole, 1-((triethoxysilyl)methyl)-2-ethyl-2,5-dihydro-1H-imidazole, 1-(3-(triethoxysilyl)propyl)-2-ethyl-2,5-dihydro-4-methyl-1H-imidazole, 2-ethyl-2,5-dihydro-1-(3-(trimethoxysilyl)propyl)-4-methyl-1H-imidazole, 1-(2-triethoxysilyl)ethyl)-2-ethyl-2,5-dihydro-4-methyl-1H-imidazole, 2-ethyl-2,5-dihydro-1-((trimethoxysilyl)methyl)-4-methyl-1H-imidazole, 1-((triethoxysilyl)methyl)-2-ethyl-2,5-dihydro-4-methyl-1H-imidazole, N-(3-triethoxysilyl)propyl)-1-methyl-1H-imidazole-5-amine, N-(3-(triethoxysilyl)propyl)-2-phenyl-2H-imidazole-1(5H)-carboxamide, N-(3-trimethoxysilyl)propyl)-1-methyl-1H-imidazole-5-amine, N-(3-(triethoxysilyl)propyl)-5-methyl-2H-benz[d]imidazole-1(4H)-carboxamide, N-(3-(triethoxysilyl)propyl)-4-methyl-2-phenyl-2H-imidazole-1(5H)-carboxamide, N-(3-(triethoxysilyl)propyl)-5,6-dimethyl-2H-benz[d]imidazole-1(4H)-carboxamide, N-(3-(triethoxysilyl)propyl)-4,5-diphenyl-1H-imidazole-1-carboxamide, N-(3-(triethoxysilyl)propyl)-2-methyl-2H-benz[d]imidazole-1(4H)-carboxamide, N-3-(triethoxysilyl)propyl)-2-ethyl-4-methyl-1H-imidazole-1-carboxamide, 1-(3-(triethoxysilyl)propyl)-2,7a-dihydro-5-methyl-1H-benz[d]imidazole, 2,7a-dihydro-1-(3-(trimethoxysilyl)propyl)-5-methyl-1H-benz[d]imidazole, 2,7a-dihydro-1-((trimethoxysilyl)methyl)-5-methyl-1H-benz[d]imidazole, 1-(2-(triethoxysilyl)ethyl)-2,7a-dihydro-5-methyl-1H-benz[d]imidazole, 1-((triethoxysilyl)methyl)-2,7a-dihydro-5-methyl-1H-benz[d]imidazole, 1-(3-(triethoxysilyl)propyl)-2,5-dihydro-4-methyl-2-phenyl-1H-imidazole, 2,5-dihydro-1-(3-(trimethoxysilyl)propyl)-4-methyl-2-phenyl-1H-imidazole, 2,5-dihydro-1-((trimethoxysilyl)methyl)-4-methyl-2-phenyl-1H-imidazole, 1-(2-(triethoxysilyl)ethyl)-2,5-dihydro-4-methyl-2-phenyl-1H-imidazole, 1-((triethoxysilyl)methyl)-2,5-dihydro-4-methyl-2-phenyl-1H-imidazole, 1-(3-(triethoxysilyl)propyl)-2,4-dihydro-5,6-dimethyl-1H-benz[d]imidazole, 2,4-dihydro-1-(3-(trimethoxysilyl)propyl)-5,6-dimethyl-1H-benz[d]imidazole, 2,4-dihydro-1-((trimethoxysilyl)methyl)-5,6-dimethyl-1H-benz[d]imidazole, 1-(2-(triethoxysilyl)ethyl)-2,4-dihydro-5,6-dimethyl-1H-benz[d]imidazole, 1-((triethoxysilyl)methyl)-2,4-dihydro-5,6-dimethyl-1H-benz[d]imidazole, 1-(3-(triethoxysilyl)propyl)-4,5-diphenyl-1H-imidazole, 1-((trimethoxysilyl)methyl)-4,5-diphenyl-1H-imidazole, 1-(3-(trimethoxysilyl)propyl)-4,5-diphenyl-1H-imidazole, 1-(2-(triethoxysilyl)ethyl)-4,5-diphenyl-1H-imidazole, 1-((triethoxysilyl)methyl)-4,5-diphenyl-1H-imidazole, 1-(3-(triethoxysilyl)propyl)-2-ethyl-4-methyl-1H-imidazole, 2-ethyl-1-((trimethoxysilyl)methyl)-4-methyl-1H-imidazole, 2-ethyl-1-(3-(trimethoxysilyl)propyl)-4-methyl-1H-imidazole, 1-(2-(triethoxysilyl)ethyl)-2-ethyl-4-methyl-1H-imidazole, 1-((triethoxysilyl)methyl)-2-ethyl-4-methyl-1H-imidazole, 1-(3-(triethoxysilyl)propyl)-2-ethyl-1H-benz[d]imidazole, 1-((trimethoxysilyl)methyl)-2-ethyl-1H-benz[d]imidazole, 1-(3-(trimethoxysilyl)propyl)-2-methyl-1H-benz[d]imidazole, 1-(2-(triethoxysilyl)ethyl)-2-methyl-1H-benz[d]imidazole, 1-((triethoxysilyl)methyl)-2-methyl-1H-benz[d]imidazole, N-(3-(triethoxysilyl)propyl)-1-ethyl-2-methyl-1H-imidazole-5-amine, N-(3-(triethoxysilyl)propyl)-1,2-dimethyl-1H-imidazole-5-amine, 1-ethyl-N-(3-(trimethoxysilyl)propyl)-2-methyl-1H-imidazole-5-amine, and N-(3-(trimethoxysilyl)propyl)-1,2-dimethyl-1H-imidazole-5-amine.

The hydrolysis, dehydration, and condensation of the complex salt of imidazole having a silane group of the formula described above and C₁-C₂₀ diiodoalkane proceed such that the imidazole becomes bound to C₁-C₂₀ diiodoalkane by crosslinking and then, gelation is induced. As a result, a product obtained by the hydrolysis, dehydration and condensation of the complex salt of the imidazole and C₁-C₂₀ diiodoalkane is formed. Although not illustrated in FIG. 1, iodine (I₂) is reacted with an iodide ion (I⁻) to form a tri-iodide ion (I₃⁻) (Operation (II) of FIG. 1).

The product obtained by the hydrolysis, dehydration and condensation of the complex salt of imidazole and C₁-C₂₀ diiodoalkane may be a compound represented by Formula 5 below.

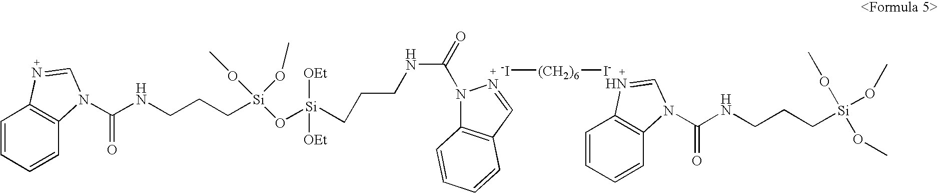

The amount of the complex salt of imidazole and C₁-C₂₀ diiodoalkane may be in the range of 10 to 50 parts by weight based on 100 parts by weight of the total weight of the electrolyte. The amount of the iodide ion (that is, the total amount of iodide ion derived from the C₁-C₂₀ diiodoalkane and added iodine) may be in the range of 10 to 30 parts by weight based on 100 parts by weight of the total weight of the electrolyte.

The silane-substituted imidazole represented by Formula 2 described above may be synthesized by the following process.

As illustrated in Reaction Scheme 1 below, benzimidazole (A) and an isocyanate compound (B) are mixed with an organic solvent, and then the mixture is refluxed to obtain the compound of Formula 2.

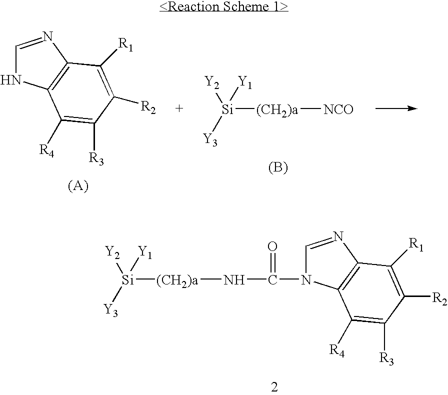

wherein R₁ through R₄, Y₁ through Y₃, and a are the same as defined in Formula 2.

As non-limiting examples, the organic solvent used in the reaction may be tetrahydrofuran, dimethyl sulfoxide, chloroform, acetone, acetonitrile, dimethyl formamide, 1,4-dioxane, diethyl ether, toluene, or ethyl acetate. The amount of the isocyanate compound (B) may be in the range of 1.01 to 1.2 moles based on 1 mole of benzimidazole (A).

The alkyl group used herein may be a linear or branched alkyl group, such as, for example, methyl, ethyl, propyl, isobutyl, sec-butyl, tert-butyl, pentyl, iso-amyl, hexyl, or the like. At least one hydrogen atom included in the alkyl group may be substituted with a halogen atom, a hydroxyl group, a nitro group, a cyano group, an amino group, an amidino group, a hydrazine group, a hydrazone group, or the like.

The alkoxy group used herein may be methoxy, ethoxy, propoxy, or the like. At least one hydrogen atom included in the alkoxy group may be substituted with a halogen atom, a hydroxyl group, a nitro group, a cyano group, an amino group, an amidino group, a hydrazine group, a hydrazone group, or the like.

The term “aryl group” as used herein refers to a carbocyclic aromatic system including at least one aromatic ring. When the aryl group includes more than one aromatic ring, the aromatic rings may be fused together or pendent. As non-limiting examples, the aryl group may be an aromatic group such as phenyl, naphthyl, tetrahydronaphthyl, or the like. In the aryl group, at least one hydrogen atom can be substituted with the same substituents as in the alkyl group described above.

The term “carbocyclic group” as used herein refers to a C₄-C₃₀ ring or ring system such as a cycloalkylene group. In the cycloalkylene group, at least one hydrogen atom can be substituted with the same substituents as in the alkyl group described above.

The definition of other groups used herein may be interpreted by referring to the definition of the above-mentioned corresponding groups. For example, the term “heteroaryl group” refers to an aryl group having at least one hetero atom.

In the electrolyte according to aspects of the present invention, the amount of the complex salt of the imidazole and C₁-C₂₀ diiodoalkane may be in the range of 10 to 50 parts by weight based on 100 parts by weight of the total weight of the electrolyte. Herein, the total weight of the electrolyte refers to the total weight of the heat treatment product of the imidazole, C₁-C₂₀ diiodoalkane and iodine (I₂), or the total weight of the product obtained by hydrolysis, dehydration and condensation of the heat treatment product of the silane-substituted imidazole, C₁-C₂₀ diiodoalkane and iodine (I₂).

When the amount of the complex salt of the imidazole and C₁-C₂₀ diiodoalkane is less than 10 parts by weight, the concentration of iodine ion in the electrolyte may be insufficient so that the current properties of a solar cell may be reduced. When the amount of the complex salt of imidazole and C₁-C₂₀ diiodoalkane is greater than 50 parts by weight, the effect of the interaction between iodine ions is increased so that the ionic conductivity may be reduced.

The electrolyte for a solar cell may further comprise at least one additive selected from nitrogen-containing additives and lithium-containing additives. The additives improve the current and voltage properties of the solar cell. The total amount of the additives may be in the range of 5 to 20 parts by weight based on 100 parts by weight of the iodide ion. When the total amount of the additives is less than 5 parts by weight based on 100 parts by weight of the iodide ion, the effect of the additive may be insignificant. On the other hand, when the total amount of the additives is greater than 20 parts by weight based on 100 parts by weight of the iodine ion, the additives may interfere with ion transfer.

As non-limiting examples, the nitrogen-containing additives may be selected from the group consisting of pyridines such as 4-butylpyridine, pyrazole, imidazole, 1,2,3-triazole, 1,2,4-triazole, tetrazole, pyridazine, pyrimidine, pyrazine, or 1,3,5-triazine; quinolines such as 2-aminoquinoline, 3-aminoquinoline, 5-aminoquinoline, 6-aminoquinoline, or the like; and amines. The lithium containing additives may be selected from the group consisting of lithium iodide (Lil), LiClO₄, LiAsF₆, LiBF₆, LiPF₄, and LiCF₃SO₃.

The electrolyte for a solar cell may further include a non-volatile or low volatile organic solvent. As non-limiting examples, the non-volatile or low volatile organic solvent may be at least one selected from the group consisting of acetonitrile (AN), ethylene glycol, butanol, isobutyl alcohol, isopentyl alcohol, isopropyl alcohol, ethyl ether, dioxane, tetrahydrobutane, tetrahydrofurane, n-butyl ether, propyl ether, isopropyl ether, acetone, methylethyl ketone, methyl butylketone, methyl isobutyl ketone, ethylene carbonate (EC), diethyl carbonate (DEC), propylene carbonate (PC), dimethyl carbonate (DMC), ethyl methyl carbonate (EMC), γ-butyrolactone (GBL), N-methyl-2-pyrrolidone, and 3-methoxypropionitrile (MP).

The amount of the non-volatile or low volatile organic solvent may be in the range of 1 to 10 parts by weight based on 100 parts by weight of the iodine ion.

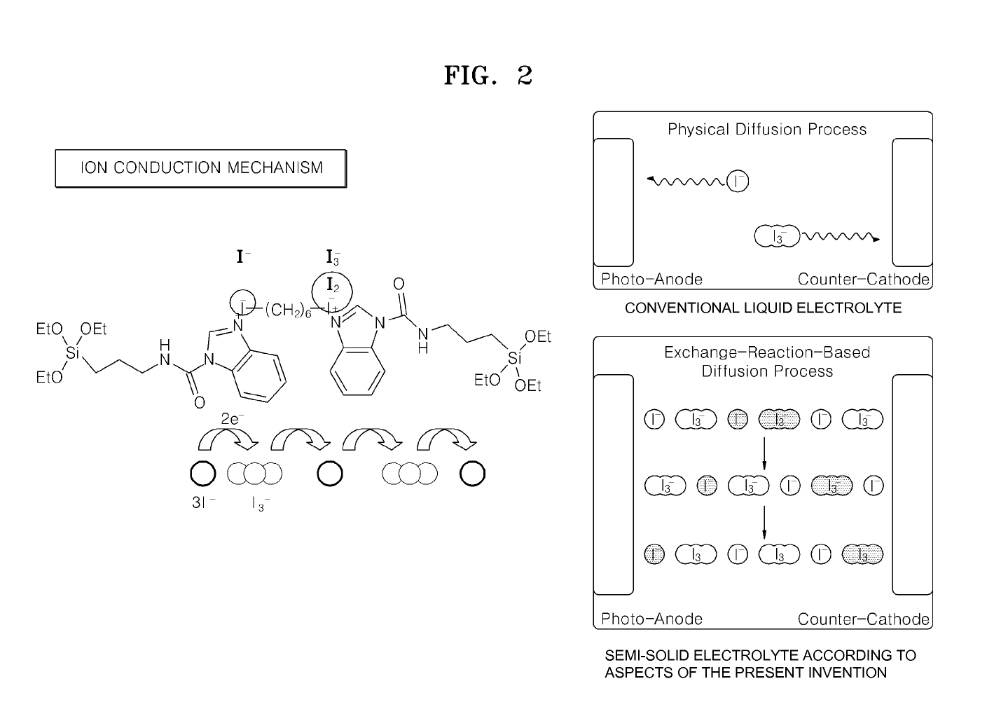

FIG. 2 is a view illustrating an ion conduction mechanism in an electrolyte according to aspects of the present invention. In the case of a conventional liquid electrolyte for a solar cell, electrons are transferred by a physical diffusion process. On the other hand, in the case of the gel-type electrolyte according to aspects of the present invention, an electron transfer from 3I⁻ to I₃⁻ occurs by an exchange-reaction-based diffusion process, that is, an electron hopping system, and thus the electrolyte according to aspects of the present invention has ionic conductivity.

Hereinafter, a method of preparing an electrolyte for a solar cell according to an embodiment of the present invention will be described.

First, an imidazole and C₁-C₂₀ diiodoalkane are mixed in a predetermined molar ratio to prepare a first mixture. The amount of the imidazole may be in the range of 1 to 2 moles based on 1 mole of the C₁-C₂₀ diiodoalkane. When the amount of the imidazole is less than 1 mole based on 1 mole of the C₁-C₂₀ diiodoalkane, unreacted C₁-C₂₀ diiodoalkane remains. When the amount of the imidazole is greater than 2 moles based on 1 mole of C₁-C₂₀ diiodoalkane, unreacted imidazole remains, which can interfere with ion transfer.

Separately, iodine and if desired, at least one additive selected from nitrogen-containing additives and lithium-containing additives are mixed, and then the first mixture is added thereto to obtain a composition used to form an electrolyte. During the preparation of the composition, additional additives may further be added thereto.

The composition used to form an electrolyte is injected into a solar cell, and the solar cell is heat treated at in the range of 50 to 70° C., and thereby, gelation is induced. As a result, a solar cell comprising a semi-solid gel-type electrolyte can be prepared. The heat treatment operation corresponds to operation (I) of FIG. 1.

When the heat treatment temperature is less than 50° C., gelation reactivity is reduced. When the heat treatment temperature is greater than 70° C., properties of organic materials inside the solar cell may be degraded.

When the imidazole is a silane-substituted imidazole, a small amount of water may be added to the electrolyte solution, and additional gelation may be induced at room temperature (20 to 25° C.) (operation (II) of FIG. 1).

After these operations, as illustrated in FIG. 1, a part of an ethoxy group bound to silicon is hydrolyzed to be converted to a hydroxyl group, resulting in the formation of a silanol group. Then, dehydration and condensation of the silanol group are sequentially performed to form a desired product.

The amount of the water may be in the range of 1 to 10 parts by weight based on 100 parts by weight of imidazole.

During the preparation of the composition used to form an electrolyte, the non-volatile or low volatile organic solvent may be added. When the organic solvent is used, it is easy to adjust the viscosity of the composition used to form an electrolyte and the ionic conductivity is improved, when the composition is injected into the solar cell.

The organic solvent described above may not be needed. For example, some materials such as molten salten (imidazolium-based iodine), and the like exist in a liquid state, and thus a solvent is not necessarily needed.

Aspects of the present invention also provide a solar cell, such as, for example, a dye-sensitized solar cell, including: a first electrode and a second electrode facing each other; a porous film, which is disposed between the first electrode and the second electrode and which adsorbs dyes; and an electrolyte according to the above embodiments is disposed between the first electrode and the second electrode.

The electrolyte is, as described above, a semi-solid electrolyte prepared using gelation in which ions are produced as in the complex salt of an imidazole and C₁-C₂₀ diiodoalkane. Since gelation in which ions are produced is used, a reduction in ionic conductivity and a reduction in efficiencies of the solar cell, due to the gelation can be minimized. In particular, to minimize the reduction in efficiencies of the solar cell due to the gelation, the gelation process is performed at a low temperature in the range of 60° C. or less. Therefore, the solar cell according to aspects of the present invention has cell stability and maximized photoelectric conversion current.

As a non-limiting example, the first electrode may be an electrode prepared by coating a conductive film comprising at least one selected from indium tin oxide, indium oxide, tin oxide, zinc oxide, sulfur oxide, fluorine oxide, and mixtures thereof, onto a transparent plastic substrate or glass substrate comprising any one of PET, PEN, PC, PP, PI, and TAC.

The porous film may have a structure in which nano particles having a nanometer-scale diameter are uniformly distributed. The porous film may be formed to maintain porosity and also have appropriate surface roughness. The porous film may comprise conductive particulates such as ITO such that electrons may be transferred easily, or a light scatterer to improve the efficiency of nanoparticles by extending an optical path. Alternatively, the porous film may comprise both the conductive particulates and the light scatterer.

The dyes that can be adsorbed onto the porous film may comprise a material that contains a Ru complex to absorb visible rays. Ru, a platinum group element, can form many different organic metal complex compounds. In addition, complexes of a metal including Al, Pt, Pd, Eu, Pb, and Ir, or the like can be used. Examples of dyes generally used include N3 dye (cis-bis(isothiocyanato)bis(2,2′-bipyridyl-4,4′-dicarboxylato)-ruthenium(II)), N719 dye (cis-bis(isothiocyanato)bis(2,2′-bipyridyl-4,4′-dicarboxylato)-ruthenium(II)-bis tetrabutylammonium), and the like.

Organic chromophores having a variety of colors are inexpensive and versatile. Thus, research into efficiency improvement of organic chromophores is being actively conducted. Non-limiting examples of organic chromophores include coumarin, pheophorbide a, which is a kind of porphyrin, or the like. Organic chromophores may be used alone or in the combination with an Ru complex. By using organic chromophores, the absorption of visible rays having a long wavelength is improved, and thus, efficiencies of the dyes can be improved.

The adsorption of the dyes onto the porous film is carried out by immersing the porous film for about 12 hours in an alcohol solution in which the dyes are dissolved.

The second electrode has a structure in which a first conductive film is coated onto a transparent plastic substrate or glass substrate, and a second conductive film comprising Pt or precious metal materials is coated onto the first conductive film. As a specific, non-limiting example, Pt may be used for the second conductive film because of its excellent reflectance.

The first electrode and the second electrode are joined to each other using a support such as an adhesive film, a thermoplastic polymer film such as “SURLYN” (DuPont), or the like, and the inside of the first electrode and the second electrode is sealed accordingly. Then, a fine hole penetrating the first electrode and the second electrode is formed, an electrolyte solution is injected between the two electrodes through the hole, and then the inside of the hole is filled and sealed with an adhesive.

Alternatively, or in addition to the support, the first electrode and the second electrode can be directly joined to each other and sealed using an adhesive such as an epoxy resin, a UV hardening agent, or the like. In this case, the two electrodes can be hardened after heat treatment or UV treatment.

The dye-sensitized solar cell according to aspects of the present invention is prepared as follows. First, the first electrode and the second electrode, which comprise a light transmissive material, are prepared, and then a porous film is formed on one surface of the first electrode. Then, dyes are adsorbed onto the porous film, the second electrode is disposed to face the porous film of the first electrode, and the interior between the porous film and the second electrode is filled with the electrolyte solution and sealed. As a result, the preparation of the dye-sensitized solar cell is completed.

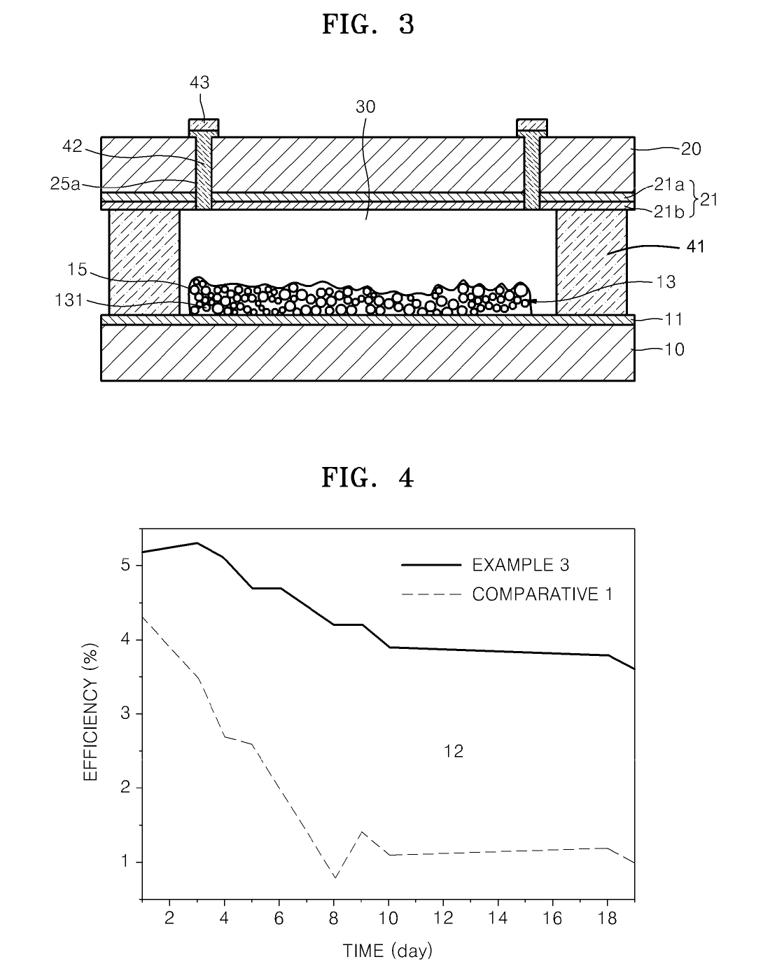

FIG. 3 is a cross-sectional view illustrating a structure of a dye-sensitized solar cell, which is a solar cell according to an embodiment of the present invention.

Referring to FIG. 3, the solar cell includes a first substrate 10 on which a first electrode 11, a porous film 13, and dyes 15 are formed and a second substrate 20 on which second electrodes 21 are formed, wherein the first substrate 10 and the second substrate 20 are disposed to face each other, and an electrolyte 30 is disposed between the first electrode 11 and the second electrode 21. A separate case (not shown) can be disposed at an outer side of the first substrate 10 and the second substrate 20. The configuration of the solar cell will now be described in more detail.

The first substrate 10, which acts as a support for supporting the first electrode 11, is transparent in order to transmit external light incident thereon. Thus, the first substrate 10 may be formed of glass or plastic. As non-limiting examples, the plastic may be polyethylene terephthalate (PET), polyethylene naphthalate (PEN), polycarbonate (PC), polypropylene (PP), polyimide (PI), triacetyl cellulose (TAC), or the like.

The first electrode 11 formed on the first substrate 10 may be formed of a transparent material such as, for example, at least one selected from indium tin oxide, indium oxide, tin oxide, zinc oxide, sulfur oxide, fluorine oxide, and mixtures thereof, ZnO—Ga₂O₃, ZnO—Al₂O₃, or the like. The first electrode 11 may comprise a single film or a laminated film made of the transparent material.

The porous film 13 is formed on the first electrode 11. The porous film 13, which is formed by a self-assembling method, contains metallic oxide particles 131 that are very fine and have a uniform average diameter. In addition, the porous film 13 may have nanoporous properties because the size of pores is also very fine and uniform.

The average diameter of the pores of the porous film 13 may be in the range of 7.5 to 15 nm. Since the porous film 13 has an appropriate average size of pores, the electrolyte 30 can be easily transferred.

As non-limiting examples, the thickness of the porous film 13 may be in the range of 10 to 3,000 nm, or more particularly in the range of 10 to 1,000 nm. However, the present invention is not limited thereto. The thickness of the porous film 13 may also vary according to technology development, and the like.

The metallic oxide particles 131 may comprise titanium oxide, zinc oxide, tin oxide, strontium oxide, indium oxide, iridium oxide, lanthanum oxide, vanadium oxide, molybdenum oxide, tungsten oxide, niobium oxide, magnesium oxide, aluminum oxide, yttrium oxide, scandium oxide, samarium oxide, gallium oxide, strontium titanium oxide, or the like. As specific non-limiting examples, the metallic oxide particles 131 may be TiO₂, SnO₂, WO₃, ZnO, or complexes thereof.

The dyes 15 that absorb external light to generate excited electrons are adsorbed onto the surface of the porous film 13. As discussed above, the dyes 15 may comprise a metal complex including Al, Pt, Pd, Eu, Pb, Ir, Ru, or the like. For example, the dye may be an organic metal complex containing Ru. Alternatively, as also discussed above, dyes comprising organic chromophores, or the like can be used. As non-limiting examples, the organic chromophores may be coumarin, porphyrin, xanthene, riboflavin, triphenyl methane, or the like. Also, combinations of metal complexes and organic chromophores may be used.

The second substrate 20, which is disposed to face the first substrate 10 and acts as a support for supporting the second electrode 21, may be transparent. Accordingly, the second substrate 20 may be made of glass or plastic as is the first substrate 10.

The second electrode 21, which formed on a lower surface of the second substrate 20 and is disposed to face the first electrode 11, includes a transparent electrode 21a and a catalyst electrode 21b. The transparent electrode 21a may be made of a transparent material such as indium tin oxide, fluorine-doped tin oxide, an antimony tin oxide, zinc oxide, tin oxide, ZnO—Ga₂O₃, ZnO—Al₂O₃, or the like. The transparent electrode 21a may comprise a single film or laminated film made of the transparent material. The catalyst electrode 21b activates a redox couple, and may be formed of platinum, ruthenium, palladium, iridium, rhodium (Rh), osmium (Os), carbon (C), WO₃, TiO₂, or the like.

The first substrate 10 and the second substrate 20 are attached to each other using an adhesive 41, and the electrolyte 30 is injected into the interior between the first electrode 11 and the second electrode 21 through holes 25a penetrating the second substrate 20 and the second electrode 21. The electrolyte 30 is also uniformly diffused into the porous film 13. The electrolyte 30 receives electrons from the second electrode 21 and transfers them to the dyes 15 through reduction and oxidation. The holes 25a penetrating the second substrate 20 and the second electrode 21 are sealed by an adhesive 42 and a cover glass 43.

The electrolyte 30 may be the ionic semi-solid gel-type electrolyte described above.

When an external light, such as sunlight, hits the interior of the solar cell, photons are absorbed into the dyes 15 so that the dyes 15 are shifted from a ground state to an excited state, thereby generating excited electrons. The excited electrons migrate into the conduction bands of the metallic oxide particles 131 of the porous film 13, and flow to an external circuit (not shown) through the first electrode 11. Thereafter, electrons are received from the second electrode 21. Meanwhile, the iodide within the electrolyte 30 is oxidized into triiodide, and accordingly the oxidized dyes 15 are reduced. The triiodide reacts with the electrons received from the second electrode 21 and is thereby reduced to iodide. The solar cell thus operates due to the migration of the electrons.

Hereinafter, aspects of the present invention will be described more specifically with reference to the following examples. The following examples are only for illustrative purposes and are not intended to limit the scope of the invention.

### Synthesis Example 1

### Synthesis of Silane-Substituted Benzimidazole of Formula 4

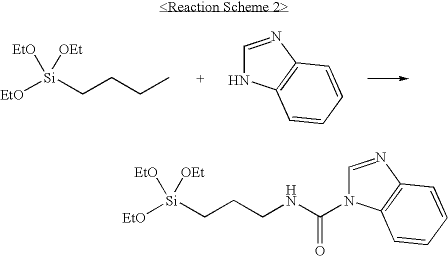

3-(trimethoxysilyl)propylisocyanate and benzimidazole in a molar ratio of 1:1 were dissolved in an anhydrous THF and mixed together, and then the mixture was refluxed at 140° C. for about 8 hours under an argon atmosphere. Subsequently, after the reaction was terminated, an organic solvent was removed using a rotary evaporator. As a result, silane-substituted benzimidazole of Formula 4 in an oil form (N-[3-(triethoxy-4-silyl)propyl]-1H-benzimidazole-1-carboxamide) was obtained. The structure of the synthesized compound, which was measured by NMR (Bruker 400 MHz) was as follows. Reagents needed for the synthesis were all purchased from Aldrich Company. ¹H NMR (400 MHz; DMSO-d₆): (ppm) 8.73 (s, 1H); 8.57 (t, 1H, NH); 8.06 (d, 1H); 7.71 (d, 1H); 7.32 (m, 2H); 3.74 (q, 6H); 3.29 (q, 2H); 1.65 (m, 2H); 1.14 (t, 9H), 0.64 (t, 2H).

### Example 1

### Preparation of Electrolyte and Manufacture of Solar Cell Using the Electrolyte (silane-substituted benzimidazole of Formula 4 and Diiodoalkane were Mixed in a Molar Ratio of 1:1)

A solution in which titanium oxide particles with a particle diameter in the range of about 5 to 15 nm were diffused was coated onto a 1 cm² area of an ITO conductive film of a first electrode using a doctor blade method. The resultant was heat treated at 450° C. for 30 minutes to prepare a porous film having a thickness of 10 μm.

Then, the resulting structure was maintained at 80° C. and immersed in a dye chromophore solution containing 0.3 mM of Ru(4,4′-dicarboxy-2,2′-bipyridine)₂(NCS)₂ dissolved in ethanol for 12 hours or more to form a dye adsorbed porous film. Thereafter, the dye adsorbed porous film was washed with ethanol and then dried at room temperature.

A second electrode was manufactured by forming a second conductive film comprising Pt on a first conductive film comprising ITO using sputtering. Fine holes for electrolyte injection were made using a drill having a diameter of 0.75 mm.

A support made of a thermoplastic polymer film having a thickness of 60 μm was disposed between the first electrode, on which the porous film was formed, and the second electrode, and the resultant was pressed at 100° C. for 9 seconds to attach the two electrodes to each other.

Then, a composition used to form an electrolyte was injected through the fine holes formed in the second electrode and then the fine holes were sealed by a cover glass and the thermoplastic polymer film. Gelation was induced using an oven at 60° C. for 30 minutes to manufacture a dye-sensitized solar cell using the gel-type electrolyte. All of reagents used in Example 1 were purchased from Aldrich company.

The composition used to form an electrolyte was prepared by the following processes.

First, the silane-substituted benzimidazole of Formula 4 prepared by Synthesis Example 1 and diiodoalkane (I(CH₂)₆I (Aldrich)) were mixed in a molar ratio of 1:1.

Separately, 0.1 M of lithium iodide, 0.05 M of iodine, and 0.5 M of 4-tert-butylpyridine were dissolved in 3-methoxypropionitrile, and then the mixture was mixed with the mixed solution of the silane-substituted benzimidazole and diiodoalkane in a volume ratio of 1:1 to prepare the composition used to form an electrolyte.

### Example 2

### Preparation of Electrolyte and Manufacture of Solar Cell Using the Electrolyte (silane-substituted benzimidazole of Formula 4 and Diiodoalkane were Mixed in a Molar Ratio of 1:2)

A gel-type electrolyte and a dye-sensitized solar cell using the same were prepared in the same manner as in Example 1, except that the silane-substituted benzimidazole synthesized by Synthesis Example 1 and diiodoalkane (Aldrich) were mixed in a molar ratio of 1:2.

### Example 3

### Preparation of Electrolyte and Manufacture of Solar Cell Using the Electrolyte (silane-substituted benzimidazole of Formula 4 and Diiodoalkane were Mixed in a Molar Ratio of 2:1)

A gel-type electrolyte and a dye-sensitized solar cell using the same were prepared in the same manner as in Example 1, except that the silane-substituted benzimidazole synthesized by Synthesis Example 1 and diiodoalkane (Aldrich) were mixed in a molar ratio of 2:1.

### Comparative Example 1

### Preparation of Liquid Electrolyte and Manufacture of Solar Cell

To compare the gel-type electrolytes of Examples 1 through 3 with a conventional electrolyte in terms of photoelectric conversion properties, a liquid electrolyte was prepared by dissolving 0.6 M of 1-hexyl-2,3-dimethylimidazolium iodide, 0.1 M of lithium iodide, 0.05 M of iodine, and 0.5 M of 4-tert-butylpyridine in 3-methoxypropionitrile.

Subsequently, the liquid electrolyte was injected into a solar cell, and the inlet of the solar cell was sealed. As a result, the manufacture of the solar cell was completed in the same manner as in Example 1.

To equally compare the liquid electrolyte with the gel-type electrolytes of Examples 1 through 3 and to evaluate the effect caused by temperature, the liquid electrolyte was heat treated using an oven at 60° C. for 30 minutes.

Ionic conductivities of the gel-type electrolyte of Example 3 and the liquid electrolyte of Comparative Example 1, before and after the heat treatment at 60° C. for 30 minutes were measured. The results are shown in Table 1 below.

TABLE 1

| | Conductivity (S/cm) | |
|---|---|---|
| | Before heat treatment | After heat treatment |
| Example 3 | 2.47E−03 | 2.61E−03 |
| Comparative Example 1 | 3.72E−02 | 3.71E−02 |

Referring to Table 1, the ionic conductivities of the liquid electrolyte of Comparative Example 1 before and after the heat treatment do not show a difference. However, the ionic conductivity of the gel-type electrolyte of Example 3 after the heat treatment is increased compared to that of the gel-type electrolyte of Example 3 before the heat treatment. From the results, it can be seen that although the imidazole and diiodoalkane are bound to each other to generate ions by heat treatment so that gelation occurs, the ionic conductivity is increased.

Photoelectric conversion properties of the solar cells manufactured by Examples 1 through 3 were measured. The results are shown in Table 2 below. Herein, the photoelectric conversion properties were measured at 100 mW/cm².

TABLE 2

| | | | | Photoelectric |
|---|---|---|---|---|
| | Open-circuit | Short-circuit | | conversion |
| | Voltage Voc | current | Fill factor | efficiency |
| | (V) | Jsc (mA · cm⁻²) | FF | η (%) |
| Example 1 | 0.71 | 13.5 | 0.51 | 4.9 |
| Example 2 | 0.71 | 13.2 | 0.50 | 4.7 |
| Example 3 | 0.72 | 14.0 | 0.52 | 5.3 |

Referring to Table 2, it can be seen that as the molar ratio of the silane-substituted benzimidazole and diiodoalkane is changed, the photoelectric conversion properties are changed. In the case of Examples 1 and 2, the mole number of diiodoalkane is more than the mole number needed for cross-linking, and thus unreacted diiodoalkane remains. No unreacted materials remained in the case of Example 3 in which 2 moles of benzimidazole and 1 mole of diiodoalkane were mixed. From the results, it can be seen that the solar cell of Example 3 exhibits the highest photoelectric conversion efficiency.

In the solar cells manufactured by Example 3 and Comparative Example 1, The photoelectric conversion properties of the solar cells of Comparative Example 1 (liquid electrolyte) and Example 3 (gel electrolyte) before and after heat treatment at 60° C. for 30 minutes were measured. The results are shown in Table 3 below. Herein, the photoelectric conversion properties were measured at 100 mW/cm².

TABLE 3

| | | | | Photoelectric |
|---|---|---|---|---|
| | Open-circuit | Short-circuit | | conversion |
| | Voltage | current | | efficiency |
| | Voc (V) | Jsc (mA · cm⁻²) | Fill factor FF | η (%) |
| Comparative Example 1: | 0.70 | 16.6 | 0.51 | 5.9 |
| before heat treatment | | | | |
| Comparative Example 1: | 0.71 | 16.0 | 0.52 | 5.9 |
| after heat treatment | | | | |
| Example 3: before heat | 0.69 | 14.1 | 0.48 | 4.6 |
| treatment | | | | |
| Example 3: after heat | 0.72 | 14.0 | 0.52 | 5.3 |
| treatment | | | | |

Referring to Table 3, degrading of properties of the solar cells due to heat treatment was not seen. On the other hand, in the case of the semi-solid electrolyte in the solar cell of Example 3, there is a difference between the efficiency before heat treatment and the efficiency after heat treatment. Without being bound to any particular theory, it is assumed that this is because gelation proceeds according to the heat treatment, and accordingly, the concentration of a free diffusion anion is reduced, resulting in a reduction in the effect of electron recombination occurring around the TiO₂ nanoparticle electrode. The solar cell using the gelated semi-solid electrode exhibits excellent photoelectric conversion efficiency, that is, 5.3% (about 90% efficiency of the liquid electrolyte), given that an average photoelectric conversion efficient of solar cells using a gel-type electrolyte is about 4%.

The durability of the solar cells of Example 3 and Comparative 1 was evaluated, and the results are shown in FIG. 4.

Referring to FIG. 4, in the case of the solar cell using the liquid electrolyte of Comparative Example 1, which has strong volatility, the efficiency of the solar cell was rapidly reduced due to volatilization and leakage of the liquid electrolyte. On the other hand, in the case of the solar cell using the non-volatile gel-type electrolyte of Example 3, the efficiency of the solar cell was decreased relatively slowly, and the efficiency was stably maintained after about 10 days.

The electrolyte according to aspects of the present invention is an ionic gel-type electrolyte that is injected into a solar cell with a low viscosity in a liquid form, and then gelated at a low temperature in the range of 60° C. or less. Thus, the electrolyte is may be used in the manufacture of the solar cell, and has higher ionic conductivity compared to a conventional gel-type electrolyte. In addition, by using the electrolyte according to aspects of the present invention, problems such as leakage and volatilization generated when a liquid electrolyte is used can be prevented, and thus the stability and durability of the solar cell are improved.

When the electrolyte, which is a semi-solid electrolyte, is used, degrading of photoelectric conversion efficiencies of the solar cell can be minimized, and a solar cell with improved lifespan, in particular, a dye-sensitized solar cell can be manufactured.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An electrolyte for a solar cell, comprising:
a complex salt of an imidazole and a C₁-C₂₀ diiodoalkane; and
an iodide ion (I⁻/I₃⁻).

2. The electrolyte of claim 1, wherein the electrolyte is produced by heat-treating the complex salt of the imidazole and C₁-C₂₀ diiodoalkane and I₂.

3. The electrolyte of claim 1, wherein the imidazole is a compound represented by Formula 1 below. 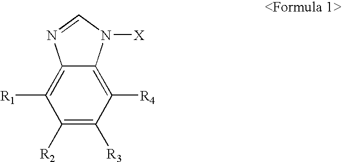
wherein R₁, R₂, R₃, and R₄ are each independently hydrogen, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₆-C₂₀ aryloxy group, a substituted or unsubstituted C₂-C₂₀ heteroaryl group, a substituted or unsubstituted C₂-C₂₀ heteroaryloxy group, a substituted or unsubstituted C₄-C₁₀ carbocyclic group, a hydroxyl group, a cyano group, or a halogen atom,
X is hydrogen, a substituted or unsubstituted C₁-C₂₀ alkyl group, a substituted or unsubstituted C₆-C₂₀ aryl group, or a group represented by the structural formula below, 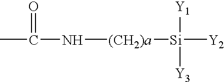
wherein Y₁, Y₂, and Y₃ are each independently a halogen atom, a hydroxyl group, a C₁-C₁₀ alkyl group, a C₁-C₁₀ alkoxy group, or hydrogen, and
a is an integer in the range of 1 through 10.

4. The electrolyte of claim 1, wherein the imidazole is at least one compound selected from the group consisting of 2-ethylimidazole, 1-acetylimidazole, 2-ethyl-4-methylimidazole, 1-allylimidazole, 2-methyl-5-nitroimidazole, ethyl 4-methyl-5-imidazolecarboxylate, 2-phenylimidazole, 1-vinylimidazole, 4,5-dichloroimidazole, 5-chloro-1-methylimidazole, 5-methylbenzimidazole, 5-chloro-1-ethyl-2-methylimidazole, 4-methyl-2-phenylimidazole, methyl-2-nitro-1-imidazoleacetate, methyl 4-imidazolecarboxylate, 2-butyl-4-chloro-5-(hydroxymethyl)imidazole, 2-butyl-4-chloro-5-formyl imidazole, 5-bromo-1-methylimidazole, 2-bromo-1-methyl-1H-imidazole, 2-iodoimidazole, 2-methylimidazole, 2-chloro-1H-imidazole, 2-methyl-5-nitroimidazole, 2-(chloromethyl)benzimidazole, 5,6-dimethylbenzimidazole, 1,2-dimethylimidazole, 4,5-diphenylimidazole, 2-ethyl-4-methylimidazole, 2-methylbenzimidazole, 1-(3-triethoxysilyl)propyl)-2-ethyl-2,5-dihydroxy-1H-imidazole, 2-ethyl-2,5-dihydro-1-(3-(trimethoxysilyl)propyl)-1H-imidazole, 1-(2-(triethoxysilyl)ethyl)-2-ethyl-2,5-dihydro-1H-imidazole, 2-ethyl-2,5-dihydro-1-((trimethoxysilyl)methyl)-1H-imidazole, 1-((triethoxysilyl)methyl)-2-ethyl-2,5-dihydro-1H-imidazole, 1-(3-(triethoxysilyl)propyl)-2-ethyl-2,5-dihydro-4-methyl-1H-imidazole, 2-ethyl-2,5-dihydro-1-(3-(trimethoxysilyl)propyl)-4-methyl-1H-imidazole, 1-(2-triethoxysilyl)ethyl)-2-ethyl-2,5-dihydro-4-methyl-1H-imidazole, 2-ethyl-2,5-dihydro-1-((trimethoxysilyl)methyl)-4-methyl-1H-imidazole, 1-((triethoxysilyl)methyl)-2-ethyl-2,5-dihydro-4-methyl-1H-imidazole, N-(3-triethoxysilyl)propyl)-1-methyl-1H-imidazole-5-amine, N-(3-(triethoxysilyl)propyl)-2-phenyl-2H-imidazole-1(5H)-carboxamide, N-(3-trimethoxysilyl)propyl)-1-methyl-1H-imidazole-5-amine, N-(3-(triethoxysilyl)propyl)-4-methyl-2-phenyl-2H-imidazole-1(5H)-carboxamide, N-(3-(triethoxysilyl)propyl)-4,5-diphenyl-1H-imidazole-1-carboxamide, N-(3-(triethoxysilyl)propyl)-2-methyl-2H-benz[d]imidazole-1(4H)-carboxamide, N-3-(triethoxysilyl)propyl)-2-ethyl-4-methyl-1H-imidazole-1-carboxamide, 1-(3-(triethoxysilyl)propyl)-2,7a-dihydro-5-methyl-1H-benz[d]imidazole, 2,7a-dihydro-1-(3-(trimethoxysilyl)propyl)-5-methyl-1H-benz[d]imidazole, 2,7a-dihydro-1-((trimethoxysilyl)methyl)-5-methyl-1H-benz[d]imidazole, 1-(2-(triethoxysilyl)ethyl)-2,7a-dihydro-5-methyl-1H-benz[d]imidazole, 1-((triethoxysilyl)methyl)-2,7a-dihydro-5-methyl-1H-benz[d]imidazole, 1-(3-(triethoxysilyl)propyl)-2,5-dihydro-4-methyl-2-phenyl-1H-imidazole, 2,5-dihydro-1-(3-(trimethoxysilyl)propyl)-4-methyl-2-phenyl-1H-imidazole, 2,5-dihydro-1-((trimethoxysilyl)methyl)-4-methyl-2-phenyl-1H-imidazole, 1-(2-(triethoxysilyl)ethyl)-2,5-dihydro-4-methyl-2-phenyl-1H-imidazole, 1-((triethoxysilyl)methyl)-2,5-dihydro-4-methyl-2-phenyl-1H-imidazole, 1-(3-(triethoxysilyl)propyl)-2,4-dihydro-5,6-dimethyl-1H-benz[d]imidazole, 2,4-dihydro-1-(3-(trimethoxysilyl)propyl)-5,6-dimethyl-1H-benz[d]imidazole, 2,4-dihydro-1-((trimethoxysilyl)methyl)-5,6-dimethyl-1H-benz[d]imidazole, 1-(2-(triethoxysilyl)ethyl)-2,4-dihydro-5,6-dimethyl-1H-benz[d]imidazole, 1-((triethoxysilyl)methyl)-2,4-dihydro-5,6-dimethyl-1H-benz[d]imidazole, 1-(3-(triethoxysilyl)propyl)-4,5-diphenyl-1H-imidazole, 1-((trimethoxysilyl)methyl)-4,5-diphenyl-1H-imidazole, 1-(3-(trimethoxysilyl)propyl)-4,5-diphenyl-1H-imidazole, 1-(2-(triethoxysilyl)ethyl)-4,5-diphenyl-1H-imidazole, 1-((triethoxysilyl)methyl)-4,5-diphenyl-1H-imidazole, 1-(3-(triethoxysilyl)propyl)-2-ethyl-4-methyl-1H-imidazole, 2-ethyl-1-((trimethoxysilyl)methyl)-4-methyl-1H-imidazole, 2-ethyl-1-(3-(trimethoxysilyl)propyl)-4-methyl-1H-imidazole, 1-(2-(triethoxysilyl)ethyl)-2-ethyl-4-methyl-1H-imidazole, 1-((triethoxysilyl)methyl)-2-ethyl-4-methyl-1H-imidazole, 1-(3-(triethoxysilyl)propyl)-2-ethyl-1H-benz[d]imidazole, 1-((trimethoxysilyl)methyl)-2-ethyl-1H-benz[d]imidazole, 1-(3-(trimethoxysilyl)propyl)-2-methyl-1H-benz[d]imidazole, 1-(2-(triethoxysilyl)ethyl)-2-methyl-1H-benz[d]imidazole, 1-((triethoxysilyl)methyl)-2-methyl-1H-benz[d]imidazole, N-(3-(triethoxysilyl)propyl)-1-ethyl-2-methyl-1H-imidazole-5-amine, N-(3-(triethoxysilyl)propyl)-1,2-dimethyl-1H-imidazole-5-amine, 1-ethyl-N-(3-(trimethoxysilyl)propyl)-2-methyl-1H-imidazole-5-amine, N-(3-(trimethoxysilyl)propyl)-1,2-dimethyl-1H-imidazole-5-amine and a compound represented by Formula 2 below.
<Formula 2> 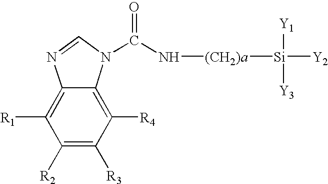
wherein R₁, R₂, R₃, and R₄ are each independently hydrogen, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₆-C₂₀ aryloxy group, a substituted or unsubstituted C₂-C₂₀ heteroaryl group, a substituted or unsubstituted C₂-C₂₀ heteroaryloxy group, a substituted or unsubstituted C₄-C₁₀ carbocyclic group, a hydroxyl group, a cyano group, or a halogen atom,
Y₁, Y₂, and Y₃ are each independently a halogen atom, a hydroxyl group, a C₁-C₁₀ alkyl group, a C₁-C₁₀ alkoxy group, or hydrogen, and
a is an integer in the range of 1 through 10.

5. The electrolyte of claim 4, wherein the compound represented by Formula 2 is at least one selected from the group consisting of N-(3-(triethoxysilyl)propyl)-2H-benz[d]imidazole-1(4H)-carboxamide, N-(3-(triethoxysilyl)propyl)-5-methyl-2H-benz[d]imidazole-1(4H)-carboxamide, and N-(3-(triethoxysilyl)propyl)-5,6-dimethyl-2H-benz[d]imidazole-1(4H)-carboxamide.

6. The electrolyte of claim 1, wherein the C₁-C₂₀ diiodoalkane is at least one selected from the group consisting of diiodohexane, diiodoheptane, and diiodononane.

7. The electrolyte of claim 1, wherein the complex salt of the imidazole and C₁-C₂₀ diiodoalkane is a compound represented by Formula 3 below.
<Formula 3> 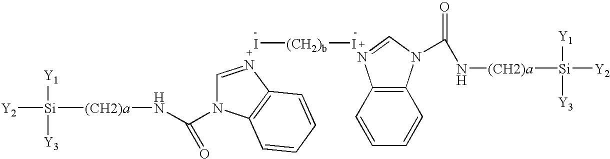
wherein Y₁, Y₂, and Y₃ are each independently a halogen atom, a hydroxyl group, a C₁-C₁₀ alkyl group, a C₁-C₁₀ alkoxy group, or hydrogen, and
a is an integer in the range of 1 to 10, and b is an integer in the range of 1 to 20.

8. The electrolyte of claim 5, wherein Y₁, Y₂, and Y₃ are each independently ethoxy group, a is 3, and b is 6.

9. The electrolyte of claim 3, wherein an amount of the complex salt of the imidazole and C₁-C₂₀ diiodoalkane is in the range of 10 to 50 parts by weight based on 100 parts by weight of the total weight of the electrolyte.

10. The electrolyte of claim 1, wherein an amount of the iodine ion is in the range of 10 to 30 parts by weight based on 100 parts by weight of the total weight of the electrolyte.

11. The electrolyte of claim 1, further comprising at least one additive selected from a nitrogen-containing additive and a lithium-containing additive.

12. The electrolyte of claim 1, further comprising a non-volatile or low-volatile organic solvent.

13. An electrolyte for a solar cell, comprising: a cation and an iodide ion (I⁻/I₃⁻), which are produced from a hydrolyzed, dehydrated and condensed product of a complex salt of a silane substituted imidazole and C₁-C₂₀ diiodoalkane and iodine (I₂).

14. The electrolyte of claim 13, wherein the silane-substituted imidazole is at least one selected from the group consisting of 1-(3-triethoxysilyl)propyl)-2-ethyl-2,5-dihydroxy-1H-imidazole, 2-ethyl-2,5-dihydro-1-(3-(trimethoxysilyl)propyl)-1H-imidazole, 1-(2-(triethoxysilyl)ethyl)-2-ethyl-2,5-dihydro-1H-imidazole, 2-ethyl-2,5-dihydro-1-((trimethoxysilyl)methyl)-1H-imidazole, 1-((triethoxysilyl)methyl)-2-ethyl-2,5-dihydro-1H-imidazole, 1-(3-(triethoxysilyl)propyl)-2-ethyl-2,5-dihydro-4-methyl-1H-imidazole, 2-ethyl-2,5-dihydro-1-(3-(trimethoxysilyl)propyl)-4-methyl-1H-imidazole, 1-(2-triethoxysilyl)ethyl)-2-ethyl-2,5-dihydro-4-methyl-1H-imidazole, 2-ethyl-2,5-dihydro-1-((trimethoxysilyl)methyl)-4-methyl-1H-imidazole, 1-((triethoxysilyl)methyl)-2-ethyl-2,5-dihydro-4-methyl-1H-imidazole, N-(3-triethoxysilyl)propyl)-1-methyl-1H-imidazole-5-amine, N-(3-(triethoxysilyl)propyl)-2-phenyl-2H-imidazole-1(5H)-carboxamide, N-(3-trimethoxysilyl)propyl)-1-methyl-1H-imidazole-5-amine, N-(3-(triethoxysilyl)propyl)-4-methyl-2-phenyl-2H-imidazole-1(5H)-carboxamide, N-(3-(triethoxysilyl)propyl)-4,5-diphenyl-1H-imidazole-1-carboxamide, N-(3-(triethoxysilyl)propyl)-2-methyl-2H-benz[d]imidazole-1(4H)-carboxamide, N-3-(triethoxysilyl)propyl)-2-ethyl-4-methyl-1H-imidazole-1-carboxamide, 1-(3-(triethoxysilyl)propyl)-2,7a-dihydro-5-methyl-1H-benz[d]imidazole, 2,7a-dihydro-1-(3-(trimethoxysilyl)propyl)-5-methyl-1H-benz[d]imidazole, 2,7a-dihydro-1-((trimethoxysilyl)methyl)-5-methyl-1H-benz[d]imidazole, 1-(2-(triethoxysilyl)ethyl)-2,7a-dihydro-5-methyl-1H-benz[d]imidazole, 1-((triethoxysilyl)methyl)-2,7a-dihydro-5-methyl-1H-benz[d]imidazole, 1-(3-(triethoxysilyl)propyl)-2,5-dihydro-4-methyl-2-phenyl-1H-imidazole, 2,5-dihydro-1-(3-(trimethoxysilyl)propyl)-4-methyl-2-phenyl-1H-imidazole, 2,5-dihydro-1-((trimethoxysilyl)methyl)-4-methyl-2-phenyl-1H-imidazole, 1-(2-(triethoxysilyl)ethyl)-2,5-dihydro-4-methyl-2-phenyl-1H-imidazole, 1-((triethoxysilyl)methyl)-2,5-dihydro-4-methyl-2-phenyl-1H-imidazole, 1-(3-(triethoxysilyl)propyl)-2,4-dihydro-5,6-dimethyl-1H-benz[d]imidazole, 2,4-dihydro-1-(3-(trimethoxysilyl)propyl)-5,6-dimethyl-1H-benz[d]imidazole, 2,4-dihydro-1-((trimethoxysilyl)methyl)-5,6-dimethyl-1H-benz[d]imidazole, 1-(2-(triethoxysilyl)ethyl)-2,4-dihydro-5,6-dimethyl-1H-benz[d]imidazole, 1-((triethoxysilyl)methyl)-2,4-dihydro-5,6-dimethyl-1H-benz[d]imidazole, 1-(3-(triethoxysilyl)propyl)-4,5-diphenyl-1H-imidazole, 1-((trimethoxysilyl)methyl)-4,5-diphenyl-1H-imidazole, 1-(3-(trimethoxysilyl)propyl)-4,5-diphenyl-1H-imidazole, 1-(2-(triethoxysilyl)ethyl)-4,5-diphenyl-1H-imidazole, 1-((triethoxysilyl)methyl)-4,5-diphenyl-1H-imidazole, 1-(3-(triethoxysilyl)propyl)-2-ethyl-4-methyl-1H-imidazole, 2-ethyl-1-((trimethoxysilyl)methyl)-4-methyl-1H-imidazole, 2-ethyl-1-(3-(trimethoxysilyl)propyl)-4-methyl-1H-imidazole, 1-(2-(triethoxysilyl)ethyl)-2-ethyl-4-methyl-1H-imidazole, 1-((triethoxysilyl)methyl)-2-ethyl-4-methyl-1H-imidazole, 1-(3-(triethoxysilyl)propyl)-2-ethyl-1H-benz[d]imidazole, 1-((trimethoxysilyl)methyl)-2-ethyl-1H-benz[d]imidazole, 1-(3-(trimethoxysilyl)propyl)-2-methyl-1H-benz[d]imidazole, 1-(2-(triethoxysilyl)ethyl)-2-methyl-1H-benz[d]imidazole, 1-((triethoxysilyl)methyl)-2-methyl-1H-benz[d]imidazole, N-(3-(triethoxysilyl)propyl)-1-ethyl-2-methyl-1H-imidazole-5-amine, N-(3-(triethoxysilyl)propyl)-1,2-dimethyl-1H-imidazole-5-amine, 1-ethyl-N-(3-(trimethoxysilyl)propyl)-2-methyl-1H-imidazole-5-amine, N-(3-(trimethoxysilyl)propyl)-1,2-dimethyl-1H-imidazole-5-amine and a compound represented by Formula 2, 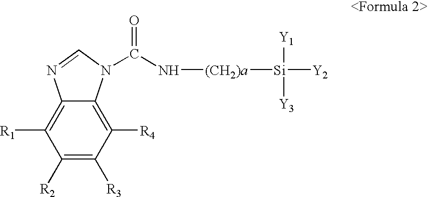
wherein R₁, R₂, R₃, and R₄ are each independently hydrogen, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₆-C₂₀ aryloxy group, a substituted or unsubstituted C₂-C₂₀ heteroaryl group, a substituted or unsubstituted C₂-C₂₀ heteroaryloxy group, a substituted or unsubstituted C₄-C₁₀ carbocyclic group, a hydroxyl group, a cyano group, or a halogen atom,
Y₁, Y₂, and Y₃ are each independently a halogen atom, a hydroxyl group, a C₁-C₁₀ alkyl group, a C₁-C₁₀ alkoxy group, or hydrogen, and
a is an integer in the range of 1 through 10.

15. The electrolyte of claim 14, wherein the compound represented by Formula 2 is at least one selected from the group consisting of N-(3-(triethoxysilyl)propyl)-2H-benz[d]imidazole-1(4H)-carboxamide, N-(3-(triethoxysilyl)propyl)-5-methyl-2H-benz[d]imidazole-1(4H)-carboxamide, and N-(3-(triethoxysilyl)propyl)-5,6-dimethyl-2H-benz[d]imidazole-1(4H)-carboxamide.

16. The electrolyte of claim 13, wherein the C₁-C₂₀ diiodoalkane is at least one selected from the group consisting of diiodohexane, diiodoheptane, and diiodononane.

17. The electrolyte of claim 13, wherein the complex salt of the imidazole and C₁-C₂₀ diiodoalkane is the compound represented by Formula 3 below. 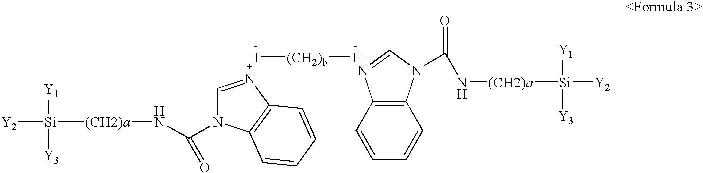
wherein Y₁, Y₂, and Y₃ are each independently a halogen atom, a hydroxyl group, a C₁-C₁₀ alkyl group, a C₁-C₁₀ alkoxy group, or hydrogen, and
a is an integer in the range of 1 to 10, and b is an integer in the range of 1 to 20.

18. The electrolyte of claim 17, wherein Y₁, Y₂, and Y₃ are each independently ethoxy group, a is 3, and b is 6.

19. The electrolyte of claim 14, wherein an amount of the complex salt of the imidazole and C₁-C₂₀ diiodoalkane is in the range of 10 to 50 parts by weight based on 100 parts by weight of the total weight of the electrolyte.

20. The electrolyte of claim 14, wherein an amount of the iodide ion is in the range of 10 to 30 parts by weight based on 100 parts by weight of the total weight of the electrolyte.

21. The electrolyte of claim 14, further comprising at least one additive selected from a nitrogen-containing additive and an lithium-containing additive.

22. The electrolyte of claim 14, further comprising a non-volatile or low-volatile organic solvent.

23. A solar cell comprising:
a first electrode and a second electrode, which face each other;
a porous film that is disposed between the first electrode and the second electrode and that includes at least one dye adsorbed thereon; and
an electrolyte disposed between the first electrode and the second electrode,
wherein the electrolyte comprises a cation of a complex salt of an imidazole and a C₁-C₂₀ diiodoalkane and an iodide ion (I⁻/I₃⁻) or a cation and an iodide ion (I⁻/I₃⁻), which are a heat-treatment product of a hydrolyzed, dehydrated and condensed product of a complex salt of a silane substituted imidazole and C₁-C₂₀ diiodoalkane and iodine (I₂).
